(19) United States
(12) Patent Application Publication
(10) Pub. No.: US 2008/0298411 A1
(43) Pub. Date: Dec. 4, 2008

(54) NITRIDE-BASED SEMICONDUCTOR LASER DEVICE AND METHOD OF MANUFACTURING THE SAME

(75) Inventor: Masayuki Hata, Kadoma-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/128,400

(22) Filed: May 28, 2008

(30) Foreign Application Priority Data
May 28, 2007 (JP) 2007-140785
Apr. 16, 2008 (JP) 2008-106552

(51) Int. Cl. H01S 5/10; H01L 33/00

(52) U.S. Cl. 372/45.01; 438/46; 257/E33.002

(57) ABSTRACT

A nitride-based semiconductor laser device includes an optical waveguide extending substantially parallel to a [0001] direction of a nitride-based semiconductor layer, a forward end face located on a forward end of the optical waveguide and formed by a substantially (0001) plane of the nitride-based semiconductor layer and a rear end face located on a rear end of the optical waveguide and formed by a substantially (000-1) plane of the nitride-based semiconductor layer, wherein an intensity of a laser beam emitted from the forward end face is rendered larger than an intensity of a laser beam emitted from the rear end face.

### CROSS-REFERENCE TO RELATED APPLICATIONS

The priority application number JP2007-140785, Nitride-Based Semiconductor Laser Device and Method of Manufacturing the Same, May 28, 2007, Masayuki Hata, JP2008-106552, Nitride-Based Semiconductor Laser Device and Method of Manufacturing the Same, Apr. 16, 2008, Masayuki Hata, upon which this patent application is based is hereby incorporated by reference.

### BACKGROUND OF THE INVENTION

1. Field of the Invention

The present invention relates to a nitride-based semiconductor laser device and a method of manufacturing the same.

2. Description of the Background Art

In a semiconductor laser device, it has been known in general that the plane orientation of a principal surface of an active layer is formed by a substantially (H, K, H-K, 0) plane, where at least either one of H and K is a nonzero integer, such as a (11-20) plane or a (1-100) plane, whereby a piezoelectric field caused in the active layer can be reduced, and consequently, luminous efficiency of a laser beam can be improved. Additionally, it has been known that a (0001) plane and a (000-1) plane are formed as a pair of cavity facets, whereby gain of the semiconductor laser device can be improved. Such a semiconductor laser device is disclosed in Japanese Patent Laying-Open No. 8-213692 and Japanese Journal of Applied Physics Vol. 46, No. 9, 2007, pp L187-L189, for example.

In the conventional semiconductor laser device disclosed in Japanese Patent Laying-Open No. 8-213692 and Japanese Journal of Applied Physics Vol. 46, No. 9, 2007, pp L187-L189, however, the (0001) plane, one of the pair of cavity facets is a Ga-polar face while the (000-1) plane, the other thereof is an N-polar face, and the plane orientations thereof are different from each other. At this time, the (000-1) plane is chemically unstable as compared with the (0001) plane and hence the (000-1) plane is likely to be formed to have a rough surface during a manufacturing process for a semiconductor laser device. Thus, scattering of the laser beam is increased due to the rough surface of the cavity facet when the (000-1) plane is formed as the cavity facet on a light emitting side. Consequently, ripple is disadvantageously generated in a far-field pattern (FFP).

### SUMMARY OF THE INVENTION

A nitride-based semiconductor laser device according to a first aspect of the present invention comprises an optical waveguide extending substantially parallel to a direction of a nitride-based semiconductor layer, a forward end face located on a forward end of the optical waveguide and formed by a substantially (0001) plane of the nitride-based semiconductor layer and a rear end face located on a rear end of the optical waveguide and formed by a substantially (000-1) plane of the nitride-based semiconductor layer, wherein an intensity of a laser beam emitted from the forward end face is rendered larger than an intensity of a laser beam emitted from the rear end face.

A method of manufacturing a nitride-based semiconductor laser device according to a second aspect of the present invention comprises steps of growing a nitride-based semiconductor element layer on a substrate such that a [0001] direction of the nitride-based semiconductor layer is perpendicular to a normal direction of a principal surface of the substrate, forming an optical waveguide extending substantially parallel to the direction in the nitride-based semiconductor element layer, forming a forward end face formed by a substantially (0001) plane of the nitride-based semiconductor layer on a forward end of the optical waveguide and forming a rear end face formed by a substantially (000-1) plane of the nitride-based semiconductor layer on a rear end of the optical waveguide, wherein a direction substantially perpendicular to the direction of the nitride-based semiconductor layer substantially coincide with the normal direction of the substrate, and an intensity of a laser beam emitted from the forward end face is larger than an intensity of a laser beam emitted from the rear end face.

Although the present invention has been described and illustrated in detail, it is clearly understood that the same is by way of illustration and example only and is not to be taken by way of limitation, the spirit and scope of the present invention being limited only by the terms of the appended claims.

### BRIEF DESCRIPTION OF THE DRAWINGS

FIG. 1 is a sectional view of a surface parallel to an optical waveguide of a semiconductor laser device, for schematically illustrating a structure of a nitride-based semiconductor laser device of the present invention;

FIG. 2 is a sectional view of a surface perpendicular to the optical waveguide of the semiconductor laser device, for schematically illustrating the structure of the nitride-based semiconductor laser device shown in FIG. 1;

FIGS. 3 and 4 are sectional views for illustrating a structure of a nitride-based semiconductor laser device according to a first embodiment of the present invention;

FIG. 5 is an enlarged sectional view of the vicinity of an active layer of the nitride-based semiconductor laser device shown in FIG. 3;

FIG. 6 is a sectional view for illustrating a structure of a nitride-based semiconductor laser device according to a second embodiment of the present invention;

FIG. 7 is a diagram for illustrating a manufacturing process for the nitride-based semiconductor laser device according to the second embodiment shown in FIG. 6;

FIG. 8 is a diagram for illustrating a manufacturing process for a nitride-based semiconductor laser device according to a third embodiment of the present invention; and

FIGS. 9 and 10 are diagrams for illustrating a manufacturing process for a nitride-based semiconductor laser device according to a fourth embodiment of the present invention.

### DESCRIPTION OF THE PREFERRED EMBODIMENTS

Embodiments of the present invention will be hereinafter described with reference to the drawings.

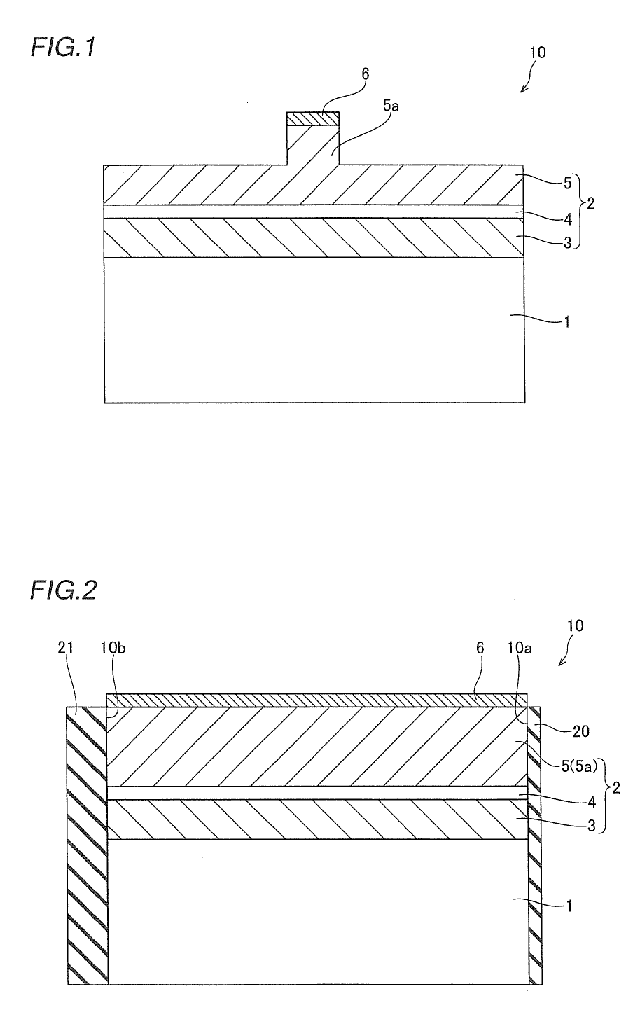

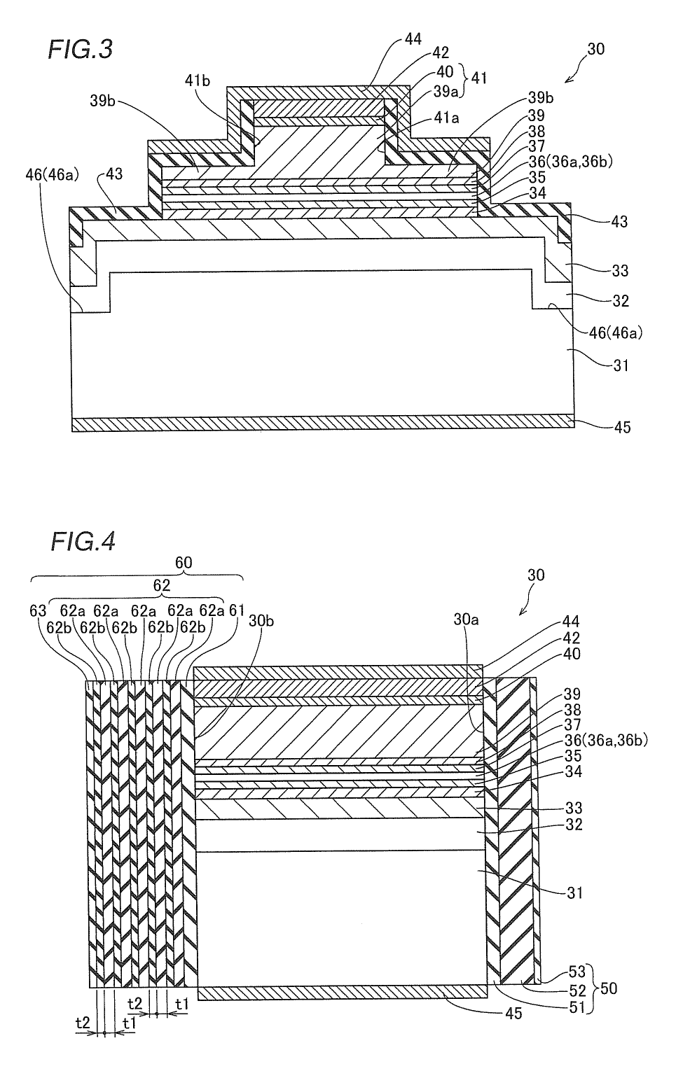

First, a concept of a nitride-based semiconductor laser device 10 of the present invention is schematically described with reference to FIGS. 1 and 2, before specifically illustrating the embodiments of the present invention.

In the nitride-based semiconductor laser device 10 of the present invention, a semiconductor laser element portion 2 is formed on an upper surface of a substrate 1 by epitaxial growth, as shown in FIG. 1. The semiconductor laser element portion 2 is an example of the “nitride-based semiconductor element layer” in the present invention. The semiconductor laser element portion 2 is formed by a nitride-based semiconductor layer having a wurtzite structure made of GaN, AlN, InN, BN, TlN or alloyed semiconductors thereof. The semiconductor laser element portion 2 is formed by a nitride-based semiconductor layer such as a first semiconductor layer 3, a active layer 4, a second semiconductor layer 5 and the like, as shown in FIG. 1. The first semiconductor layer 3 and the second semiconductor layer 5 have opposite conductivity types respectively. The first semiconductor layer 3 is formed by a first cladding layer (not shown) having a band gap larger than the active layer 4 and the second semiconductor layer 5 is formed by a second cladding layer (not shown) having a band gap larger than the active layer 4. In particular, GaN, AlGaN or the like is employed for the first cladding layer and the second cladding layer. The first semiconductor layer 3, the active layer 4 and the second semiconductor layer 5 are each an example of the “nitride-based semiconductor element layer” in the present invention.

A light guiding layer having an intermediate band gap between those of the first semiconductor layer 3 and the active layer 4 may be formed between the first semiconductor layer 3 and the active layer 4. A light guiding layer having an intermediate band gap between those of the active layer 4 and the second semiconductor layer 5 may be formed between the active layer 4 and the second semiconductor layer 5. As shown in FIG. 1, an electrode 6 is formed on an upper surface of the second semiconductor layer 5. A contact layer (not shown) preferably having a band gap smaller than the second semiconductor layer 5 is formed between the second semiconductor layer 5 and the electrode 6.

As shown in FIG. 1, the active layer 4 may be undoped or doped with Si, and In_Ga₁₋ₓN (0≦x1) is particularly employed as a material of the active layer 4. The active layer 4 has a multiple quantum well (MQW) structure obtained by alternately stacking the four barrier layers and the three well layers with each other. The active layer 4 may be formed by a single layer or a single quantum well (SQW) structure. The barrier layers and the well layers forming the active layer 4 are each an example of the “nitride-based semiconductor element layer” in the present invention.

According to the present invention, the plane orientation of the principal surface of the active layer 4 is a substantially (H, K, -H-K, 0) plane, where at least either one of H and K is a nonzero integer, such as a (11-20) plane or a (1-100) plane. According to this structure, a piezoelectric field caused in the active layer 4 can be reduced and hence luminous efficiency of the semiconductor laser element portion 2 can be improved.

According to the present invention, the semiconductor laser element portion 2 is formed with a ridge portion 5a extending in a substantially [0001] direction on the second semiconductor layer 5 as shown in FIGS. 1 and 2, whereby an optical waveguide structure is so formed as to extend in the substantially [0001] direction. A method of forming the optical waveguide structure is not restricted to a method of forming the ridge portion, but the optical waveguide structure may be formed by a buried heterostructure. The optical waveguide has an emission face (forward end face) 10a on a first end thereof and a rear face (rear end face) 10b on an end of the optical waveguide on a side opposite to the emission face 10a. The emission face 10a and the rear face 10b are examples of the “forward end face” and the “rear end face” in the present invention respectively.

According to the present invention, the emission face 10a is a substantially (0001) plane having a polarity of a group III element such as a Ga-polarity and the rear face 10b is a substantially (000-1) plane. The emission face 10a and the rear face 10b are formed by etching such as dry etching, or cleavage or polishing. Alternatively, a facet formed by crystal growth such as selective growth may be employed as the emission face 10a or the rear face 10b. The emission face 10a and the rear face 10b may be formed by the same method or different methods. For example, a facet formed by selective growth may be employed the emission face 10a while the rear face 10b may be formed by etching.

When at least one of the emission face 10a and the rear face 10b is formed by cleavage, the plane orientation of the principal surface of the active layer 4 is preferably in the range of about ±0.3 degrees from the (H, K, -H-K, 0) plane. The plane orientations of the emission face 10a and the rear face 10b formed by cleavage are preferably in the range of about ±0.3 degrees from the (0001) plane and the (000-1) plane respectively. When both of the emission face 10a and the rear face 10b are formed by a method other than etching, polishing or cleavage such as selective growth, the plane orientation of the principal surface of the active layer 4 is preferably in the range of about 25 degrees from the (H, K, -H-K, 0) plane. The plane orientations of the emission face 10a and the rear face 10b formed by the method other than etching, polishing or cleavage such as selective growth are preferably in the range of ±about 25 degrees from the (0001) plane and the (000-1) plane respectively. However, the emission face 10a and the rear face 10b are preferably substantially perpendicular (90 degrees±5 degrees) to the principal surface of the active layer 4.

The depth of each of recess portions on the emission face 10a is preferably smaller than the depth of each of recess portions on the rear face 10b. According to this structure, excellent FFP can be obtained in a laser operation. The depth of each of the recess portions on the emission face 10a is preferably at most ½ of the depth of each of the recess portions on the rear face 10b. In other words, the depth of each of the recess portions on the rear face 10b is formed to be at least twice the depth of each of the recess portions on the emission face 10a, whereby the surface of the rear face 10b can be easily cleaned. When the wavelength of the laser beam is λ and the effective refractive index of the optical waveguide is n, the depth of each of the recess portions on the rear face 10b is preferably smaller than λ/(2n). The depth of each of the recess portions on the rear face 10b is smaller than λ/(2n), whereby the reflectance on the rear face 10b can be increased. The depth of each of the recess portions on the emission face 10a is preferably smaller than λ/(4n). The depth of each of the recess portions on the emission face 10a is smaller than λ/(4n), whereby an excellent FFP can be obtained in a laser operation. The depths of the recess portions on the emission face 10a and the rear face 10b can be measured with a transmission electron microscope (TEM) or an atomic force microscope. The case where the depth of each of the recess portions on the emission face 10a is smaller than the depth of each of the recess portions on the rear face 10b includes a case where the roughness of the emission face 10a is small beyond measure with cross-section TEM.

The emission face 10a and the rear face 10b may be separately formed by etching. In this case, the condition of dry etching in forming the emission face 10a and the condition of dry etching in forming the rear face 10b are preferably different from each other.

As shown in FIG. 2, dielectric films 20 and 21 are preferably formed on the emission face 10a and the light reflecting surface 10b respectively. According to the present invention, the intensity of a laser beam emitted from the emission face 10a is rendered larger than the intensity of a laser beam emitted from the rear face 10b. For this purpose, the reflectance of the forward end face is rendered lower than the reflectance of the rear end face. A dielectric multilayer film is formed on at least one of the forward end face and the rear end face in order that the reflectance of the forward end face is rendered lower than the reflectance of the rear end face. For example, the dielectric film 21 of the rear face 10b is so formed as to have reflectance higher than that of the dielectric film 20 of the emission face 10a. In particular, the dielectric film 21 of the rear face 10b is formed by a multilayer reflector obtained by stacking two or more layers made of a material having a high refractive index and a material having a low reflectance respectively for obtaining a high reflective index. On the other hand, the dielectric film 20 of the emission face 10a is preferably an antireflection film. The aforementioned dielectric films 20 and 21 are preferably formed on the emission face 10a and the rear face 10b preferably after surfaces of the emission face 10a and the rear face 10b are cleaned by plasma treatment in a vacuum apparatus. MgO, Al₂O₃, SiO₂, TiO₂, ZrO₂, Nb₂O₅, HfO₂, Ta₂O₅, AlN, Si₃N₄, MgF₂, CaF₂, SrF₂, BaF₂ or the like may be employed as materials of the dielectric films 20 and 21. The dielectric film 20 and the dielectric film 21 are examples of the “first dielectric film” and the “second dielectric film” in the present invention respectively.

The substrate 1 may be a growth substrate or a support substrate. When the substrate 1 is the growth substrate, the substrate 1 is formed by a nitride-based semiconductor substrate or a substrate made of a material other than nitride-based semiconductor. An α-SiC, ZnO, sapphire, spinel, or LiAlO₃ substrate having a hexagonal structure or a rhombohedral structure may be employed as the substrate made of the material other than nitride-based semiconductor, for example. On the other hand, the nitride-based semiconductor substrate is preferably employed in order to obtain a nitride-based semiconductor layer (semiconductor laser element portion 2) having the most excellent crystallinity.

When the nitride-based semiconductor substrate, the α-SiC substrate or the ZnO substrate is employed as the substrate 1, the active layer 4 whose plane orientation identical with the plane orientation of the growth substrate is the principal surface can be formed on the growth substrate (substrate 1) by employing the substrate whose plane orientation is the substantially (H, K, -H-K, 0) plane such as a [11-20] plane or a [1-100] plane. When at least one of the emission face 10a and the rear face 10b is formed by cleavage, the growth substrate is preferably in the range of about ±0.3 degrees from the (H, K, -H-K, 0) plane. When the both of the emission face 10a and the rear face 10b are formed by the method other than etching, polishing or cleavage such as selective growth, the plane orientation of the growth substrate is preferably in the range of ±about 25 degrees from the (H, K, -H-K, 0) plane. When the sapphire substrate is employed as the substrate 1, the substrate whose plane orientation is a (1-102) plane is employed, whereby the active layer 4 having the (1-100) plane as the principal surface can be formed on the growth substrate. When a γ-LiAlO₃ is employed as the substrate 1, the active layer 4 having the (1-100) plane as the principal surface is formed on the growth substrate by employing the substrate whose plane orientation is a (100) plane. When an electrically conductive growth substrate is employed as the substrate, an electrode layer (not shown) may be formed on a surface of the growth substrate, opposite to a side on which the semiconductor layer (semiconductor laser element portion 2) is bonded. When the semiconductor is the growth substrate, the first semiconductor layer 3 may have the same conductivity type as the conductivity type of the growth substrate.

When the support substrate is employed as the substrate 1, the support substrate (substrate 1) and the semiconductor laser element portion 2 are bonded to each other through solder. The support substrate (substrate 1) may be an electrically conductive substrate or an insulating substrate. A metal plate such as Cu—W, Al and Fe—Ni or a semiconductor substrate such as single-crystalline Si, SiC, GaAs and ZnO or a polycrystalline AlN substrate may be employed as the electrically conductive support substrate (substrate 1). Alternately, a conductive resin film in which conductive grains of a metal or the like are dispersed, a composite material of a metal and a metal oxide may be employed. A composite material of carbon and metal consisting of a graphite particle sintered body impregnated with metal may be alternatively employed. When the electrically conductive support substrate (substrate 1) is employed, an electrode layer (not shown) may be formed on a surface of the support substrate, opposite to a side on which the semiconductor layer (semiconductor laser element portion 2) is bonded.

Embodiments embodying the aforementioned concept of the present invention will be hereinafter described with reference to the drawings.

### First Embodiment

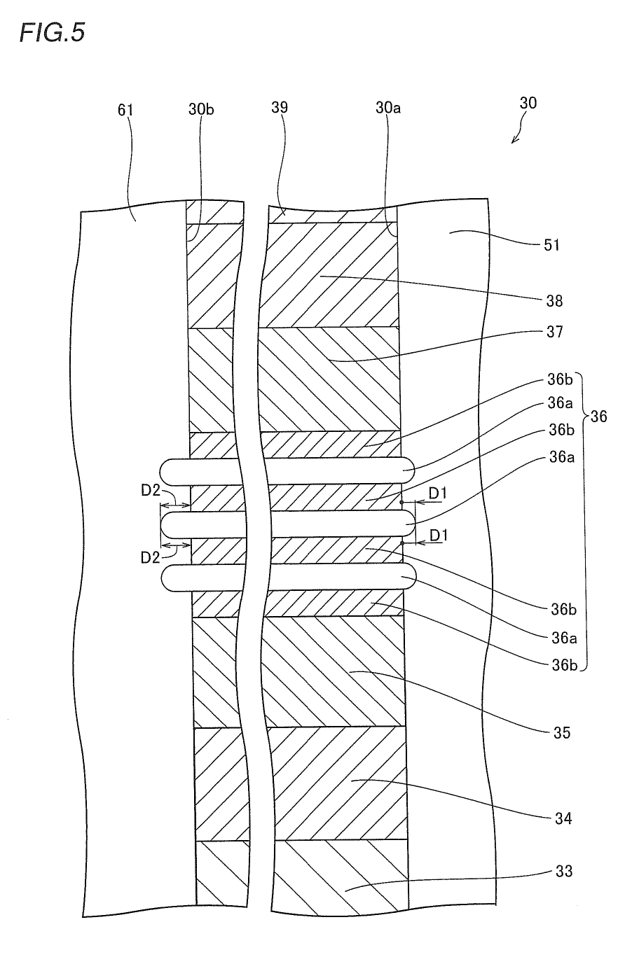

A structure of a nitride-based semiconductor laser device 30 according to a first embodiment of the present invention will be now described with reference to FIGS. 3 to 5.

In the nitride-based semiconductor laser device 30 according to the first embodiment of the present invention, an n-type layer 32 having a thickness of about 100 μm and made of n-type GaN, doped with Si, having a dose of about 5×10¹⁸ cm⁻³ is formed on an n-type GaN substrate 31 having a thickness of about 100 μm, doped with Si, having a carrier concentration of about 5×10¹⁸ cm⁻³, as shown in FIG. 3. The n-type GaN substrate 31 is misoriented by about 0.3 degrees from the (11-20) plane toward a [000-1] direction. Step portions 46 (depth: about 0.5 μm, width: about 20 μm) extending in the [0001] direction are previously formed on an upper surface of the n-type GaN substrate 31. These step portions 46 are so formed as to be located on both side portions of the nitride-based semiconductor laser device 30. An n-type cladding layer 33 having a thickness of about 400 nm and made of n-type Al_{0.07}Ga_{0.93}N, doped with Si, having a dose of about 5×10¹⁸ cm⁻³ and a carrier concentration of about 5×10¹⁸ cm⁻³ is formed on the n-type layer 32.

An n-type carrier blocking layer 34 having a thickness of about 5 nm and made of n-type Al_{0.16}Ga_{0.84}N, doped with Si, having a dose of about 5×10¹⁸ cm⁻³ and a carrier concentration of about 5×10¹⁸ cm⁻³ is formed on the n-type cladding layer 33. An n-type light guiding layer 35 having a thickness of about 100 nm and made of n-type GaN, doped with Si, having a dose of about 5×10¹⁸ cm⁻³ and a carrier concentration of about 5×10¹⁸ cm⁻³ is formed on the n-type carrier blocking layer 34. An active layer 36 is formed on the n-type light guiding layer 35. This active layer 36 has an MQW structure in which four barrier layers 36a of undoped In_{0.02}Ga_{0.98}N having a thickness of about 20 nm and three well layers 36b of undoped In_{0.6}Ga_{0.4}N having a thickness of about 3 nm are alternately formed.

As shown in FIG. 3, a p-type light guiding layer 37 having a thickness of about 100 nm and made of p-type GaN, doped with Mg, having a dose of about 4×10¹⁹ cm⁻³ and a carrier concentration of about 5×10¹⁷ cm⁻³ is formed on the active layer 36. A p-type cap layer 38 having a thickness of about 20 nm and made of p-type Al_{0.16}Ga_{0.84}N, doped with Mg, having a dose of about 4×10¹⁹ cm⁻³ and a carrier concentration of about 5×10¹⁷ cm⁻³ is formed on the p-type light guiding layer 37.

A p-type cladding layer 39 having a projecting portion 39a and planar portions 39b other than the projecting portion 39a and made of p-type Al_{0.07}Ga_{0.93}N, doped with Mg, having a dose of about 4×10¹⁹ cm⁻³ and a carrier concentration of about 5×10¹⁷ cm⁻³ is formed on the p-type cap layer 38. The thickness of each of the planar portions 39b of the p-type cladding layer 39 is about 80 nm on both sides of the projecting portion 39a. The height from the planar portions 39b to the projecting portion 39a of the p-type cladding layer 39 is about 320 nm and the width of the projecting portion 39a is about 1.75 μm.

A p-type contact layer 40 having a thickness of about 10 nm and made of p-type In_{0.02}Ga_{0.98}N, doped with Mg, having a dose of about 4×10¹⁹ cm⁻³ and a carrier concentration of about 5×10¹⁷ cm⁻³ is formed on the projecting portion 39a of the p-type cladding layer 39. A ridge portion 41 having a first side surface 41a and a second side surface 41b located on a side opposite to the first side surface 41a is formed by the p-type contact layer 40 and the projecting portion 39a of the p-type cladding layer 39. A lower portion of the ridge portion 41 has a width of about 1.75 μm and is formed in a shape extending in the [0001] direction. An optical waveguide extending in the [0001] direction is formed on a portion including the active layer 36 located below the ridge portion 41. The n-type cladding layer 33, the n-type carrier blocking layer 34, the n-type light guiding layer 35, the active layer 36, the barrier layers 36a, the well layers 36b, the p-type light guiding layer 37, the p-type cap layer 38, the p-type cladding layer 39 and the p-type contact layer 40 are each an example of the “nitride-based semiconductor element layer” in the present invention.

A p-side ohmic electrode 42 constituted by a Pt layer having a thickness of about 5 nm, a Pd layer having a thickness of about 100 nm and an Au layer having a thickness of about 150 nm from the lower layer toward the upper layer is formed on the p-type contact layer 40 constituting the ridge portion 41. A current narrowing layer 43 made of an SiO₂ film (insulating film), having a thickness of about 250 nm is formed on regions other than an upper surface of the p-side ohmic electrode 42. A p-side pad electrode 44 made of a Ti layer having a thickness of about 100 nm, a Pd layer having a thickness of about 100 nm and an Au layer having a thickness of about 3 μm from the lower layer toward the upper layer is formed on a prescribed region on the current narrowing layer 43, to be in contact with the upper surface of the p-type ohmic electrode 42.

As shown in FIG. 3, an n-side electrode 45 is formed on a lower surface of the n-type GaN substrate 31. This n-side electrode 45 is constituted by an Al layer having a thickness of about 10 nm, a Pt layer having a thickness of about 20 nm and an Au layer having a thickness of about 300 nm successively from a side of a lower surface of the n-type GaN substrate 31.

According to the first embodiment, an emission face 30a formed by a cleavage plane of the (0001) plane having a Ga-polarity is formed on one end of the optical waveguide and a rear face 30b formed by a cleavage plane of the (000-1) plane having an N-polarity is formed on the other end of the optical waveguide. The nitride-based semiconductor laser device 30 is formed such that the intensity of a laser beam emitted from the emission face 30a is larger than the intensity of a laser beam emitted from the rear face 30b. The emission face 30a and the rear face 30b are examples of the “forward end face” and the “rear end face” in the present invention respectively. As shown in FIG. 4, a dielectric multilayer film 50 having reflectance of about 5%, formed by an AlN film 51 having a thickness of about 10 nm, an Al₂O₃ film 52 having a thickness of about 85 nm and an AlN film 53 having a thickness of about 10 nm successively from a side closer to a semiconductor layer is formed on the emission face 30a of the laser beam. A dielectric multilayer film 60 having reflectance of about 95%, formed by an AlN film 61 having a thickness of about 10 nm, a multilayer reflector 62 formed by five SiO₂ films 62a each having a thickness t1 of about 70 nm as low refractive index films and five TiO₂ films 62b each having a thickness t2 of about 45 nm as high refractive index films, and an AlN film 63 having a thickness of about 10 nm successively from a side closer to the semiconductor layer is formed on the rear face 30b of the laser beam. The dielectric multilayer film 50 and the dielectric multilayer film 60 are examples of the “first dielectric film” and the “second dielectric film” in the present invention respectively. The SiO₂ films 62a and the TiO₂ films 62b are examples of the “low refractive index films” and the “high refractive index films” in the present invention respectively.

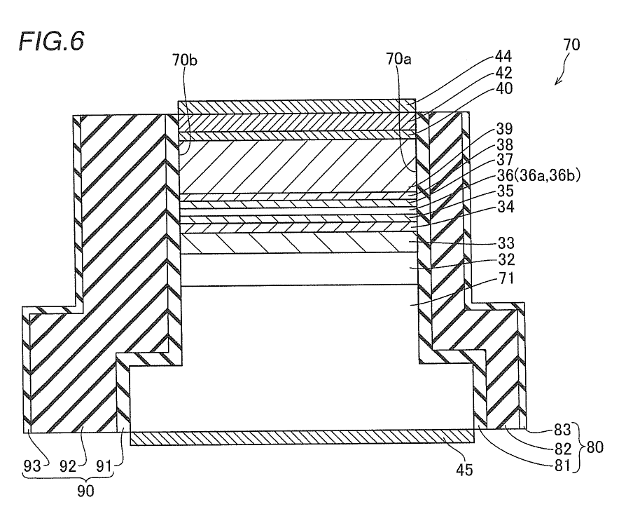

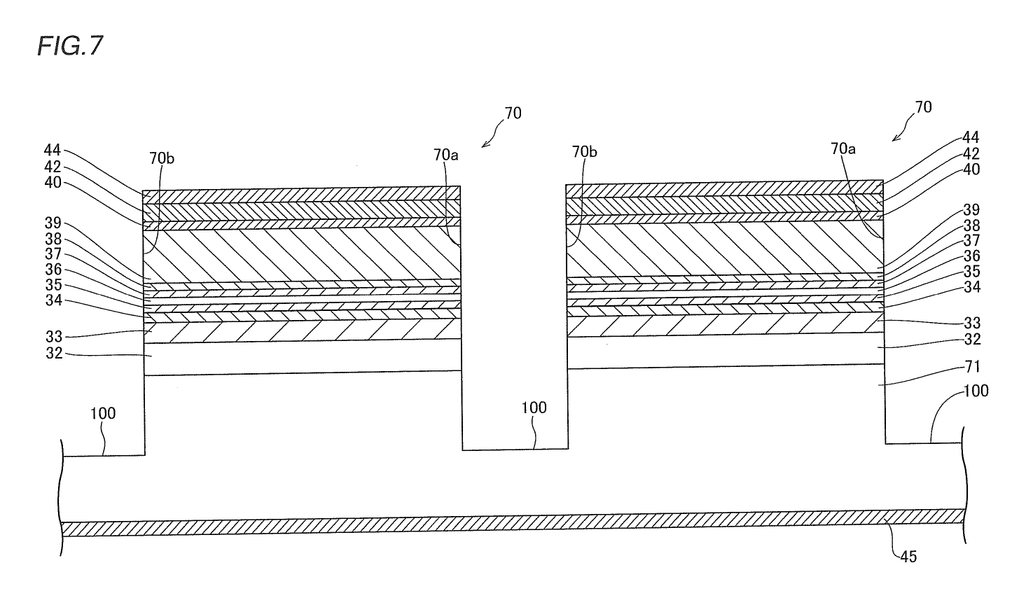

According to the first embodiment, the barrier layers 36a on a side of the emission face 30a of the active layer 36 are formed to be adjacent to the well layers 36b and concaved with respect to the well layers 36b by depth D1, while the n-type cladding layer 33, the n-type carrier blocking layer 34, the p-type cap layer 38 and the p-type cladding layer 39 are formed to be concaved with respect to the well layers 36b, as shown in FIG. 5. As shown in FIG. 6, the barrier layers 36a on a side of the rear face 30b of the active layer 36 are formed to be adjacent to the well layers 36b and concaved with respect to the well layers 36b by depth D2. The depth D1 (see FIG. 5) of each of recess portions on the emission face 30a is about 1 nm while the depth D2 (see FIG. 6) of each of recess portions on the rear face 30b is about 6 nm. The depth D2 of each of the recess portions on the rear face 30b is rendered smaller than the depth D1 of each of the recess portions on the emission face 30a (D1<D2). In this case, in particular, the depth D1 of each of the recess portions on the emission face 30a is preferably at most ½ of the depth D2 of each of the recess portions on the rear face 30b. Therefore, an FFP having small ripple can be obtained by employing the (0001) plane with small roughness as the emission face 30a. On the other hand, even the (000-1) plane with large roughness is employed as the rear face 30b, the dielectric multilayer film 60 having high reflectance is formed on the rear face 30b and hence reduction in the reflectance on the rear face 30b can be suppressed.

According to the first embodiment, the depth D2 (about 6 nm) of each of the recess portions on the rear face 30b is rendered smaller than the thickness t2 (about 45 nm) (see FIG. 4) of each of the high refractive index films (TiO₂ films 62b) which is the thinner film of the multiplayer reflector (D2<t2), as shown in FIG. 5. This is because difficulty in forming the dielectric multilayer film 60 having high reflectance is avoided when the depth D2 of each of the recess portions on the rear face 30b is larger than the thickness t2 of each of the high refractive index films (TiO₂ films 62b) which is the thinner film of the multiplayer reflector.

According to the first embodiment, the depth D1 (see FIG. 5) of each of the recess portions on the emission face 30a is rendered smaller than λ/(4n) when the wavelength of the laser beam is λ and the effective refractive index of the optical waveguide (portion of the active layer 36 below the ridge portion 41) is n. The depth D2 (see FIG. 5) of each of the recess portions on the rear face 30b is rendered smaller than λ/(2n).

A manufacturing process for the nitride-based semiconductor laser device 30 according to the first embodiment will be now described with reference to FIGS. 3 and 4.

As shown in FIG. 3, the n-type layer 32 (thickness: about 100 nm), the n-type cladding layer 33 (thickness: about 400 nm), the n-type carrier blocking layer 34 (thickness: about 5 nm), the n-type light guiding layer 35 (thickness: about 100 nm), the active layer 36 (total thickness: about 90 nm), the p-type light guiding layer 37 (thickness: about 100 nm), the p-type cap layer 38 (thickness: about 20 nm), the p-type cladding layer 39 (thickness: about 400 nm) and the p-type contact layer 40 (thickness: about 10 nm) are successively formed on the n-type GaN substrate 31 previously formed with the grooves 46a (step portions 46) (depth: about 0.5 μm, width: about 40 μm) extending in the [0001] direction in a period of about 400 μm by metal organic vapor phase epitaxy (MOVPE). Thereafter the p-side ohmic electrode 42, the current narrowing layer 43 and the p-side pad electrode 44 are formed after annealing for activation of p-type dopant and formation of the ridge portion 41. The n-side electrode 45 is formed on the lower surface of the n-type GaN substrate 31.

A method of forming the dielectric multilayer film and the cavity facets constituting the nitride-based semiconductor laser device 30 will be now described. Scribed grooves extending in a [1-100] are formed on prescribed portions by laser scribing or mechanical scribing. The scribed grooves are formed in the form of a broken line on portions except the ridge portion 41.

According to the first embodiment, the n-type GaN substrate 31 formed with the aforementioned semiconductor laser structure is so cleaved as to form the cleavage planes of the (0001) plane and the (000-1) plane, thereby forming structures each of which has the form of a bar. Thereafter each of substrates formed with the cleavage planes is introduced in an electron cyclotron resonance (ECR) sputtering apparatus.

According to the first embodiment, the emission face 30a formed by the cleavage plane of the (0001) plane is cleaned by applying ECR plasma to the emission face 30a (see FIG. 4) for five minutes. The ECR plasma is generated under a condition of microwave output of 500 W in a nitrogen gas atmosphere of about 0.02 Pa. At this time, the emission face 30a (see FIG. 4) is slightly etched. At this time, RF power is not applied to a sputtering target. Thereafter the dielectric multilayer film 50 (see FIG. 4) is formed on the emission face 30a by ECR sputtering.

According to the first embodiment, the rear face 30b formed by the cleavage plane of the (000-1) plane is cleaned by applying ECR plasma to the rear face 30b (see FIG. 4) of the cleavage plane of the (000-1) plane for five minutes similarly to the aforementioned step of cleaning the emission face 30a. At this time, the rear face 30b is slightly etched. At this time, RF power is not applied to a sputtering target. Thereafter the dielectric multilayer film 60 (see FIG. 4) is formed on the emission face 30b by ECR sputtering.

In these cleaning steps, the (000-1) plane is chemically unstable as compared with the (0001) plane and hence the roughness formed on the emission face 30a is remarkable as compared with the roughness formed on the rear face 30b. The substantial (0001) plane having a Ga-polarity unlikely to forming the roughness on the surface is employed as the emission face 30a of the laser beam through the manufacturing processes, and hence scattering of the laser beam on the emission face 30a in a laser operation can be suppressed. Consequently, an excellent FFP can be obtained in a laser operation.

When the In composition of the well layers 36b is high, the roughness is further remarkable. This is because difference of compositions of the material of the well layers 36b and the material of barrier layers, the light guiding layer or the cladding layer is increased and the roughness becomes more remarkable in the cleaning step. In particular, when the well layers are made of InₓGa₁₋ₓN (0.5<x≦1) having the composition of In larger than the composition of Ga, the roughness is further remarkable.

Therefore, when the well layers are made of InₓGa₁₋ₓN (0.5<x≦1), the substantial (0001) plane is preferably employed as the emission face 30a in order to obtain the excellent FFP in the laser operation.

Thereafter the n-type GaN substrate 31 in the form of a bar is separated into chips on the center of each groove 46a (step portion 46) (width: about 40 μm) formed on the n-type GaN substrate 31, thereby forming the nitride-based semiconductor laser devices 30 according to the first embodiment.

According to the first embodiment, the method comprises the step of cleaning the emission face 30a and rear face 30b by applying the ECR plasma after cleavage, the nitride-based semiconductor laser device 30 suppressing deterioration of the vicinity of facets of the optical waveguide or catastrophic optical damage (COD) can be easily formed by cleaning.

According to the first embodiment, even the emission face 30a and the rear face 30b are formed in the roughness through the steps of cleaning the emission face 30a and the rear face 30b, the FFP having small ripple can be obtained by employing the (0001) plane having the small roughness as the emission face 30a. Even the (000-1) plane having the large roughness is employed as the rear face 30b, on the other hand, the dielectric multilayer film 60 having high reflectance is formed on the rear face 30b, and hence reduction in reflectance on the rear face 30b can be suppressed.

The nitride-based semiconductor laser device 30 according to the first embodiment is formed in the aforementioned manner.

According to the first embodiment, as hereinabove described, the emission face 30a is formed by the substantial (0001) plane having large laser beam intensity and the rear face 30b is formed by the substantial (000-1) plane having the small laser beam intensity, whereby the substantial (0001) plane constituting the emission face 30a is chemically stable as compared with the substantial (000-1) plane and hence the roughness is unlikely to be formed. Thus, scattering of the laser beam on the emission face 30a having the large laser beam intensity in the laser operation can be suppressed. Consequently, the excellent FFP can be obtained in the laser operation.

According to the first embodiment, the depth D1 of each of the recess portions on the emission face 30a is rendered smaller than the depth D2 of each of the recess portions on the rear face 30b, whereby the excellent FFP can be obtained in the laser operation.

According to the first embodiment, the depth D1 of each of the recess portions on the emission face 30a is at most ½ of the depth D2 of each of the recess portions on the rear face 30b, whereby the depth D2 of each of the recess portions on the rear face 30b is relatively larger than depth D1 of each of the recess portions on the emission face 30a and hence the surface of the rear face 30b can be easily cleaned.

According to the first embodiment, the dielectric multilayer film 50 is formed on the emission face 30a, whereby the reflectance of the emission face 30a can be easily lower than the reflectance of the rear face 30b by the dielectric multilayer film 50.

According to the first embodiment, the dielectric multilayer film 60 is formed on the rear face 30b, whereby the reflectance of the rear face 30b can be easily controlled by the dielectric multilayer film 60.

According to the first embodiment, the dielectric multilayer film 60 includes the multilayer reflector 62 formed by the SiO₂ films 62a and the TiO₂ films 62b and the depth D2 of each of the recess portions on the rear face 30b is rendered smaller than the thickness t2 of the TiO₂ films 62b, whereby the reflectance of the rear face 30b can be increased.

According to the first embodiment, the depth D1 of each of the recess portions on the emission face 30a is rendered smaller than λ/(4n) when the wavelength of the laser beam is λ and the effective refractive index of the optical waveguide is n (portion of the active layer 36 below the ridge portion 41), whereby the excellent FFP can be obtained in the laser operation.

According to the first embodiment, the depth D2 of each of the recess portions on the rear face 30b is rendered smaller than λ/(2n) when the wavelength of the laser beam is λ and the effective refractive index of the optical waveguide is n (portion of the active layer 36 below the ridge portion 41), whereby the reflectance of the rear face 30b can be increased.

### Second Embodiment

Referring to FIG. 6, step portions are formed on optical waveguide ends of a nitride-based semiconductor laser device 70 according to a second embodiment dissimilarly to the aforementioned first embodiment.

According to the second embodiment of the present invention, a semiconductor laser structure similar to the first embodiment except for the optical waveguide ends is formed on an n-type GaN substrate 71 having a thickness of about 100 μm, doped with oxygen, having a carrier concentration of about 5×10¹⁸ cm⁻³, as shown in FIG. 6.

According to the second embodiment, the step portions are formed on the n-type GaN substrate 71 of the optical waveguide ends are formed as shown in FIG. 6. The optical waveguide has a first end formed with an emission face 70a of a (0001) plane having a Ga-polarity by dry etching and a second end formed with a rear face 70b of a (000-1) plane having an N-polarity by dry etching. The emission face 70a and the rear face 70b are examples of the “forward end face” and the “rear end face” in the present invention respectively.

As shown in FIG. 6, a dielectric multilayer film 80 having reflectance of about 5%, formed by an AlN film 81 (thickness: about 20 nm), an Al_{2X}Si_{Y}O_{3X+2Y} (X=0.9, Y=0.1) film 82 (thickness: about 85 nm) and an AlN film 83 (thickness: about 10 nm) successively from a side closer to a semiconductor layer is formed on the emission face 70a of the laser beam. A dielectric multilayer film 90 having reflectance of about 95%, formed by an AlN film 91 (thickness: about 20 nm), a multilayer reflector 92 laminated by five SiO₂ films 62a (thickness: about 70 nm) as low refractive index films and five Al_{2X}Si_{Y}O_{3X+2Y} (X=0.9, Y=0.1) films (thickness: about 50 nm) as high refractive index films, and an AlN film 93 (thickness: about 10 nm) successively from a side closer to the semiconductor layer is formed on the rear face 70b of the laser beam. The dielectric multilayer film 80 and the dielectric multilayer film 90 are examples of the “first dielectric film” and the “second dielectric film” in the present invention respectively.

According to the second embodiment, the depth of each recess portion on the emission face 70a is about 5 nm and the depth of each recess portion on the rear face 70b is about 15 nm. The emission face 70a and the (1-100) plane form an angle of about 89 degrees and the rear face 70b and the (1-100) plane form an angle of about 87 degrees.

The remaining structure of the nitride-based semiconductor laser device 70 according to the second embodiment is similar to the aforementioned first embodiment.

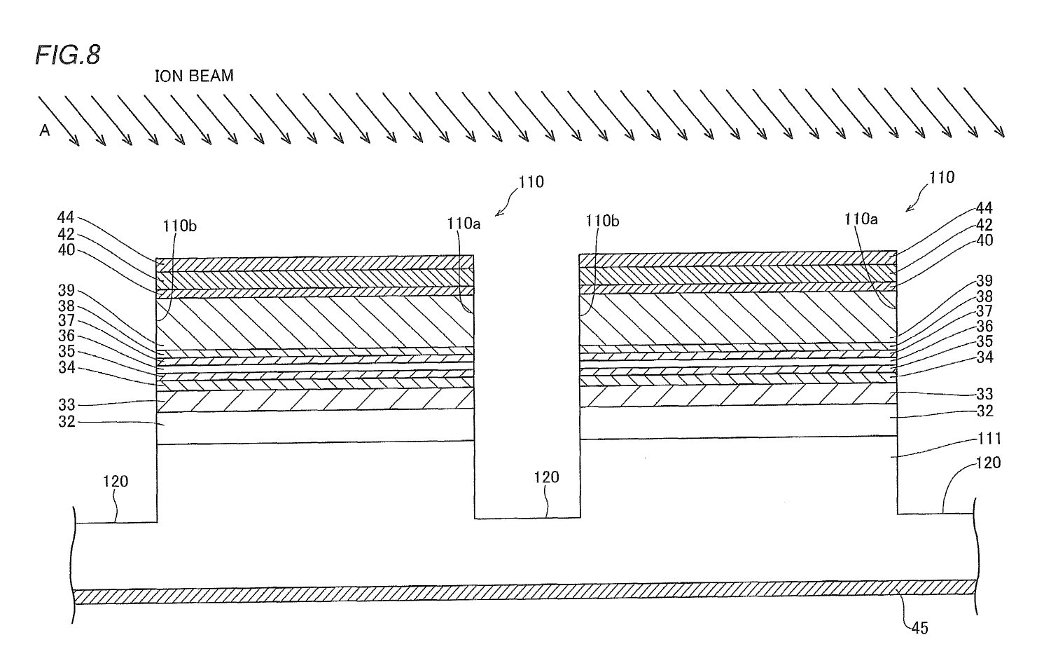

A manufacturing process for the nitride-based semiconductor laser device 70 according to the second embodiment will be now described with reference to FIG. 7.

First, the semiconductor laser structure is formed on the n-type GaN substrate 71 through a manufacturing process similar to the aforementioned manufacturing process of the first embodiment.

A method of forming the dielectric multilayer film and the cavity facets constituting the nitride-based semiconductor laser device 70 will be now described.

As shown in FIG. 7, in the n-type GaN substrate 71 formed with the semiconductor laser structure, dry etching is performed from a surface of the p-side pad electrode 44 to reach the n-type GaN substrate 71, whereby forming grooves 100 (width: about 40 μm) extending in a [11-20] direction. Dry etching such as reactive ion etching by Cl₂ or the like is applied for forming substantially (0001) plane and substantially (000-1) plane on side surfaces of the grooves 100. Then the n-type GaN substrate 71 is divided along the grooves 100, thereby forming separated structures each of which has the form of a bar. Thereafter the dielectric multilayer film 80 is formed on the emission face 70a and the dielectric multilayer film 90 is formed on the rear face 70b after cleaning the emission face 70a and the rear face 70b by irradiating ECR plasma, similarly to the first embodiment.

The nitride-based semiconductor laser device 70 according to the second embodiment is formed in the aforementioned manner.

According to the second embodiment, as hereinabove described, the condition of etching is controlled by applying dry etching when the emission face 70a and the rear face 70b of the laser beam are formed, whereby the nitride-based semiconductor laser device 70 can be easily formed such that the roughness of the emission face 70a having large laser beam intensity is smaller than that of the rear face 70b having small laser beam intensity. The remaining effects of the second embodiment are similar to those of the aforementioned first embodiment.

### Third Embodiment

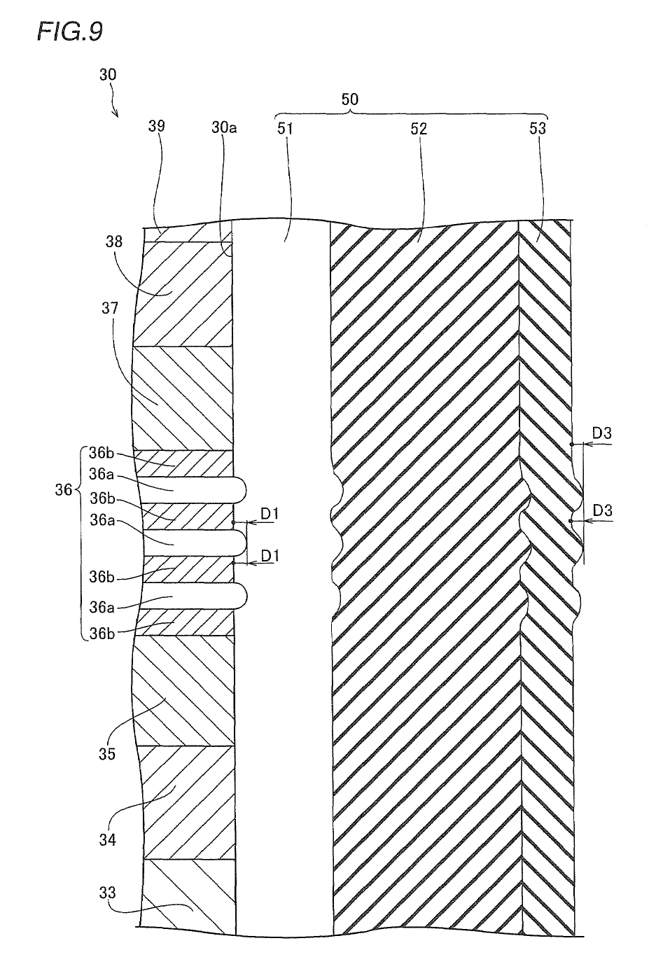

Referring to FIGS. 7 and 8, a rear face 10b is formed by dry etching after a step of forming grooves 120 by dry etching to form an emission face 110a and the rear face 10b in a nitride-based semiconductor laser device 110 according to a third embodiment, dissimilarly to the aforementioned second embodiment. The emission face 110a and the rear face 10b are examples of the “forward end face” and the “rear end face” in the present invention respectively.

As shown in FIG. 7, the grooves 120 extending in a [11-20] direction is formed on an n-type GaN substrate 111 formed with a semiconductor laser structure by dry etching similarly to the second embodiment.

According to the third embodiment, an ion beam in an oblique direction (along arrow A) is applied to the n-type GaN substrate 111 so as not to be applied to a (0001) plane, as shown in FIG. 8, whereby only a (000-1) plane is etched by dry etching such as reactive ion beam etching (RIBE). In other words, according to the third embodiment, a roughness of the (000-1) plane (rear face 10b) is formed to have further planarity (reduce the depth of each recess portions) as compared with the roughness of the (000-1) plane (rear face 70b) of the second embodiment. Thus, the depth of each of the recess portions on the rear face 10b is about 10 nm. For example, etching gas adjusted to partial pressure ratio of CH₄ gas: H₂ gas: Ar gas: N₂ gas=5:15:3:3 is employed in RIBE.

Thereafter the n-type GaN substrate 111 is divided along the grooves 120, thereby forming a separated structure in the form of a bar. Thereafter a dielectric multilayer film 80 is formed on the emission face 110a and a dielectric multilayer film 90 is formed on a rear face 110b after cleaning the emission face 110a and the rear face 110b respectively, similarly to the first and second embodiments.

The remaining structure of the nitride-based semiconductor laser device 110 according to the third embodiment is similar to that of the nitride-based semiconductor laser device according to the aforementioned second embodiment. The nitride-based semiconductor laser device 110 according to the third embodiment is formed in the aforementioned manner.

According to the third embodiment, as hereinabove described, only the rear face 110b of the grooves 120 formed by dry etching is dry etched (RIBE), whereby the rear face 110b formed by a substantially (000-1) plane likely to become rough can be provided with more planarity and hence scattering of the laser beam on the rear face 110b in a laser operation is suppressed. Consequently, the nitride-based semiconductor laser device 110 in which reduction in reflectance on the rear face 10b is suppressed can be easily manufactured. The remaining effects of the third embodiment is similar to those of the aforementioned first and second embodiments.

### Fourth Embodiment

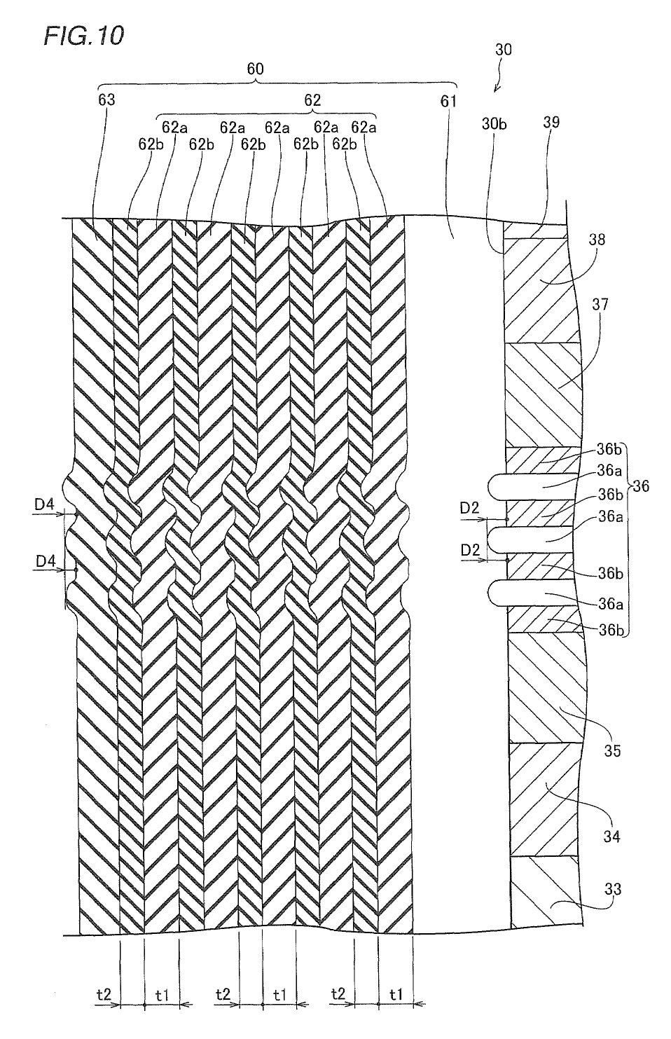

Referring to FIGS. 4, 9 and 10, cleavage planes (emission face 30a and rear face 30b) are first formed and an ECR plasma is applied to the emission face 30a (see FIG. 9) formed by a (0001) plane for five minutes, whereby the emission face 30a is cleaned and formed to have a roughness having a depth D1 of about 1 nm in a manufacturing process of a nitride-based semiconductor laser device 30 according to a fourth embodiment, similarly to the manufacturing process of the nitride-based semiconductor laser device according to the aforementioned first embodiment. Thereafter an AlN film 51 having a thickness of about 10 nm is formed by ECR sputtering according to the fourth embodiment. Then the ECR plasma is applied to the AlN film 51 for one minute under the same condition as the step of cleaning the emission face 30a, whereby a depth D3 of each of recess portions on an opposite surface of the AlN film 51 to the emission face 30a is reduced by about 0.5 nm. As shown in FIG. 4, a dielectric multilayer film 50 having reflectance of about 5% is fabricated by successive deposition of an Al₂O₃ film 52 having a thickness of about 85 nm and an AlN film 53 having a thickness of about 10 nm on the AlN film 51. Consequently, the depth D3 (about 0.5 nm) of each of the recess portions on the opposite surface of each film of the dielectric multilayer film 50 to the emission face 30a is rendered smaller than a depth D2 (about 6 nm) of each of recess portions on the rear face 30b (see FIG. 10) (D3<D2), as shown in FIG. 9.

In the manufacturing process of the nitride-based semiconductor laser device 30 according to the fourth embodiment, the ECR plasma is applied to the rear face 30b (see FIG. 10) formed by the (0001) plane for five minutes similarly to the manufacturing process of the nitride-based semiconductor laser device according to the aforementioned first embodiment, whereby the rear face 30b formed by the cleavage plane of a (000-1) plane is cleaned and formed to have a roughness having the depth D2 of about 6 nm.

According to the fourth embodiment, an AlN film 61 having a thickness of about 10 nm is first formed by ECR sputtering. Then the ECR plasma is applied to the AlN film 61 for four minutes under the same condition as the step of cleaning the rear face 30b, whereby a depth D4 of each of recess portions on an opposite surface of the AlN film 61 to the rear face 30b is reduced by about 1 nm. As shown in FIG. 4, a dielectric multilayer film 60 having reflectance of about 95% is fabricated by successive deposition of a multiplayer reflector 62 (laminated by five SiO₂ films 62a each having a thickness of about 70 nm as low refractive index films and five TiO₂ films 62b each having a thickness of about 45 nm as high refractive index films) and an AlN film 63 having a thickness of about 10 nm on the AlN film 61. Consequently, the depth D4 (about 1 nm) of each of the recess portions on the opposite surfaces of each film of the dielectric multilayer film 60 to the rear face 30b is rendered smaller than a depth D2 (about 6 nm) of each of recess portions on the rear face 30b (D4<D2), as shown in FIG. 10. The nitride-based semiconductor laser device 30 according to the fourth embodiment is formed in the aforementioned manner.

In the manufacturing process for the nitride-based semiconductor laser device 30 according to the fourth embodiment, as hereinabove described, the depth D3 of each of the recess portions on the opposite surface of each film of the dielectric multilayer film 50 to the emission face 30a is rendered smaller than the depth D2 of each of the recess portions on the rear face 30b, whereby the depth D2 of each of the recess portions on the rear face 30b is relatively larger than the depth D3 of each of the recess portions on the opposite surface of each film of the dielectric multilayer film 50 to the emission face 30a and hence the surface of the rear face 30b can be easily cleaned.

In the manufacturing process for the nitride-based semiconductor laser device 30 according to the fourth embodiment, the depth D4 of each of the recess portions on the opposite surfaces of each film of the dielectric multilayer film 60 to the rear face 30b is rendered smaller than the depth D2 of each of the recess portions on the rear face 30b, whereby the depth D2 of each of the recess portions on the rear face 30b is relatively larger than the depth D4 of each of the recess portions on the opposite surfaces of each film of the dielectric multilayer film 60 to the rear face 30b and hence the surface of the rear face 30b can be easily cleaned. The remaining effects of the fourth embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

While AlN is employed as the dielectric films of the uppermost surfaces of the dielectric multilayer films formed on the cavity facets (the emission face and the rear face) of the nitride-based semiconductor laser device in each of the aforementioned first to fourth embodiments, the present invention is not restricted to this but a nitride film such as SiNₓ, GaN and BN, a ZrO₂ film or HfO₂ may be alternatively employed as the dielectric films of the uppermost surfaces of the dielectric multilayer films.

While AlN is employed as the dielectric films in contact with the emission face and the rear face of the nitride-based semiconductor laser device in each of the aforementioned first to fourth embodiments, the present invention is not restricted to this but a nitride film such as SiNₓ, GaN and BN, a ZrO₂ film or HfO₂ may be alternatively employed.

While the multilayer reflector formed by alternately stacking the five low refractive index films and the high refractive index films is provided in each of the aforementioned first to fourth embodiments, the number of the layers stacked is not restricted to this.

While the cavity facets (both of the emission face and the rear face) of the nitride-based semiconductor laser device are cleaned by the ECR plasma in each of the aforementioned first to fourth embodiments, the present invention is not restricted to this but only one of the emission face and the rear face may be cleaned or none of the faces may be cleaned.

While the In composition x of the InₓGa₁₋ₓN well layers 36b is 0.6 in each of the aforementioned first to fourth embodiments, the present invention is not restricted to this but x=0, x=0.15, x=0.5, x=0.85 or x=1 may alternatively be employed, for example.

While the manufacturing process for the nitride-based semiconductor laser device comprises a step of reducing the roughness of the rear face 10b (reducing the depth of each of the recess portions) in the aforementioned third embodiment, the present invention is not restricted to this but the manufacturing process for the nitride-based semiconductor laser device may alternatively comprises a step of reducing the roughness of the emission face 110a.

What is claimed is:

1. A nitride-based semiconductor laser device comprising:
an optical waveguide extending substantially parallel to a [0001] direction of a nitride-based semiconductor layer;
a forward end face located on a forward end of said optical waveguide and formed by a substantially (0001) plane of said nitride-based semiconductor layer; and
a rear end face located on a rear end of said optical waveguide and formed by a substantially (000-1) plane of said nitride-based semiconductor layer, wherein
an intensity of a laser beam emitted from said forward end face is rendered larger than an intensity of a laser beam emitted from said rear end face.

2. The nitride-based semiconductor laser device according to claim 1, wherein
a first dielectric film is formed on said forward end face.

3. The nitride-based semiconductor laser device according to claim 2, wherein
a depth of a recess portion of a roughness on an opposite surface of said first dielectric film to said forward end face is smaller than a depth of a recess portion of a roughness of said rear end face.

4. The nitride-based semiconductor laser device according to claim 1, wherein
a second dielectric film is formed on said rear end face.

5. The nitride-based semiconductor laser device according to claim 4, wherein
a depth of a recess portion of a roughness on an opposite surface of said second dielectric film to said rear end face is smaller than a depth of a recess portion of a roughness of said rear end face.

6. The nitride-based semiconductor laser device according to claim 4, wherein
said second dielectric film includes a multilayer reflector laminated by a high refractive index film and a low refractive index film, and
a depth of a recess portion of a roughness on said rear end face is smaller than a thickness of said high refractive index film.

7. The nitride-based semiconductor laser device according to claim 1, wherein
a depth of a recess portion of a roughness on said forward end face is smaller than a depth of a recess portion of a roughness on said rear end face.

8. The nitride-based semiconductor laser device according to claim 1, wherein
a depth of a recess portion of a roughness on said forward end face is smaller than λ/(4n), where a wavelength of said laser beam is λ and an effective refractive index of said optical waveguide is n.

9. The nitride-based semiconductor laser device according to claim 1, wherein
a depth of a recess portion of a roughness on said rear end face is smaller than λ/(2n), where a wavelength of said laser beam is λ and an effective refractive index of said optical waveguide is n.

10. The nitride-based semiconductor laser device according to claim 7, wherein
said depth of said recess portion of said roughness on said forward end face is at most ½ of said depth of said recess portion of said roughness on said rear end face.

11. A method of manufacturing a nitride-based semiconductor laser device, comprising steps of:
growing a nitride-based semiconductor element layer on a substrate such that a [0001] direction of said nitride-based semiconductor layer is perpendicular to a normal direction of a principal surface of said substrate;
forming an optical waveguide extending substantially parallel to said [0001] direction on said nitride-based semiconductor element layer;
forming a forward end face formed by a substantially (0001) plane of said nitride-based semiconductor layer on a forward end of said optical waveguide; and
forming a rear end face formed by a substantially (000-1) plane of said nitride-based semiconductor layer on a rear end of said optical waveguide, wherein
a direction substantially perpendicular to said [0001] direction of said nitride-based semiconductor layer substantially coincide with said normal direction of said substrate, and
an intensity of a laser beam emitted from said forward end face is larger than an intensity of a laser beam emitted from said rear end face.

12. The method of manufacturing a nitride-based semiconductor laser device according to claim 11, wherein
said step of forming said forward end face or said rear end face includes a step of forming said forward end face or said rear end face by etching.

13. The method of manufacturing a nitride-based semiconductor laser device according to claim 12, wherein
said step of forming said forward end face or said rear end face by etching includes a step of forming such that a depth of a recess portion of a roughness of said forward end face is rendered smaller than a depth of a recess portion of a roughness of said rear end face by first dry etching.

14. The method of manufacturing a nitride-based semiconductor laser device according to claim 13, wherein
said depth of said recess portion of said roughness of said forward end face is at most ½ of said depth of said recess portion of said roughness of said rear end face.

15. The method of manufacturing a nitride-based semiconductor laser device according to claim 11, wherein
said step of forming said forward end face or said rear end face includes a step of forming said forward end face or said rear end face by cleavage.

16. The method of manufacturing a nitride-based semiconductor laser device according to claim 11, further comprising a step of cleaning at least one of said forward end face and said rear end face.

17. The method of manufacturing a nitride-based semiconductor laser device according to claim 16, wherein
said step of cleaning at least one of said forward end face and said rear end face includes a step of cleaning at least one of said forward end face and said rear end face by electron cyclotron resonance plasma.

18. The method of manufacturing a nitride-based semiconductor laser device according to claim 11, further comprising steps of:
forming a first dielectric film on said forward end face, and
reducing a depth of a recess portion of a roughness on an opposite surface of said first dielectric film to said forward end face.

19. The method of manufacturing a nitride-based semiconductor laser device according to claim 11, further comprising steps of:
forming a second dielectric film on said rear end face, and
reducing a depth of a recess portion of a roughness on an opposite surface of said second dielectric film to to said rear end face.

20. The method of manufacturing a nitride-based semiconductor laser device according to claim 13, wherein
said step of forming said forward end face or said rear end face by etching includes a step of reducing said depth of said recess portion of said roughness of said rear end face by etching said rear end face by second dry etching.
